(19) United States
(12) Patent Application Publication
(10) Pub. No.: US 2025/0087561 A1
(43) Pub. Date: Mar. 13, 2025

(54) POWER DEVICE CELL AND POWER ELECTRONICS ASSEMBLY INCLUDING THE POWER DEVICE CELL

(71) Applicant: Infineon Technologies Austria AG, Villach (AT)

(72) Inventors: Martial Duchamp, München (DE); Christian Schiele, München (DE); Fabien Thion, München (DE)

(21) Appl. No.: 18/466,378

(22) Filed: Sep. 13, 2023

(51) Int. Cl. H01L 23/492; H01L 23/31; H01L 23/495; H05K 1/18

(52) U.S. Cl. CPC H01L 23/4924; H01L 23/3121; H01L 23/315; H01L 23/4922; H01L 23/49513; H05K 1/183; H01L 24/32; H01L 2224/32245; H01L 2924/10253; H01L 2924/10272; H01L 2924/13055; H01L 2924/13091; H05K 2201/10166

(57) ABSTRACT

A power device cell includes: a metallic body having a first main surface, a second main surface opposite the first main surface, and a side face vertically extending between the first and second main surfaces; a vertical power semiconductor die in a recess formed in the first main surface of the metallic body; and an organic and/or glass electrical insulator covering the second main surface of the metallic body such that the power device cell is electrically insulated at least at a first side that includes the organic and/or glass electrical insulator. The organic and/or glass electrical insulator is confined to the metallic body. A backside of the vertical power semiconductor die is configured to be at a different electric potential than a frontside of the vertical power semiconductor die. The metallic body is at the same electric potential as the backside of the vertical power semiconductor die.

### BACKGROUND

For high voltage applications that utilize vertical power semiconductor devices such as vertical power transistors, the backside of the power semiconductor device has to be electrically insulated from the heat sink since the backside is electrically active. For example, in a power device cell, the backside of the power device cell is electrically connected to the backside of the power semiconductor die and thus at the same electrical potential as the backside of the die. When embedded into a PCB (printed circuit board), a laminate layer must be introduced during the PCB manufacturing process to electrically isolate the backside of the power device cell from the metallization of the PCB. However, the standard laminate used in PCB processes has low thermal conductivity (˜0.65K/W) which limits thermal dissipation of the die losses and limits overall performance of the die. More expensive laminates could be used (˜6.5 K/W) but at the price of a higher cost and are typically introduced on the entire area of the PCB, making a high performing electrical insulation too costly for most applications. Also, the presence of a continuous laminate layer between the electrically actives parts and the heat sink limits heat dissipation. A conventional approach to overcome this limitation involves drilling vias through the laminate where electrical isolation is not needed, which adds cost twice: the laminate material cost where not needed and drilling of the vias and filling with conductive material (usually copper).

Hence, there is a need form an improved power device cell design.

### SUMMARY

According to an embodiment of a power device cell, the power device cell comprises: a metallic body having a first main surface, a second main surface opposite the first main surface, and a side face vertically extending between the first main surface and the second main surface; a vertical power semiconductor die in a recess formed in the first main surface of the metallic body; and an organic and/or glass electrical insulator covering the second main surface of the metallic body such that the power device cell is electrically insulated at least at a first side that includes the organic and/or glass electrical insulator, wherein the organic and/or glass electrical insulator is confined to the metallic body, wherein a backside of the vertical power semiconductor die is configured to be at a different electric potential than a frontside of the vertical power semiconductor die, wherein the metallic body is at the same electric potential as the backside of the vertical power semiconductor die.

According to an embodiment of a power electronics assembly, the power electronics assembly comprises: a printed circuit board; and a power device cell embedded in the printed circuit board, wherein the power device cell comprises: a metallic body having a first main surface, a second main surface opposite the first main surface, and a side face vertically extending between the first main surface and the second main surface; a vertical power semiconductor die in a recess formed in the first main surface of the metallic body; and an organic and/or glass electrical insulator covering the second main surface of the metallic body such that the power device cell is electrically insulated at least at a first side that includes the organic and/or glass electrical insulator, wherein the organic and/or glass electrical insulator is confined to the metallic body, wherein a backside of the vertical power semiconductor die is configured to be at a different electric potential than a frontside of the vertical power semiconductor die, wherein the metallic body is at the same electric potential as the backside of the vertical power semiconductor die.

According to another embodiment of a power electronics assembly, the power electronics assembly comprises: a metallic frame; and a power device cell mounted to the metallic frame, wherein the power device cell comprises: a metallic body having a first main surface, a second main surface opposite the first main surface, and a side face vertically extending between the first main surface and the second main surface; a vertical power semiconductor die in a recess formed in the first main surface of the metallic body; and an organic and/or glass electrical insulator covering the second main surface of the metallic body such that the power device cell is electrically insulated at least at a first side that includes the organic and/or glass electrical insulator, wherein the organic and/or glass electrical insulator is confined to the metallic body, wherein a backside of the vertical power semiconductor die is configured to be at a different electric potential than a frontside of the vertical power semiconductor die, wherein the metallic body is at the same electric potential as the backside of the vertical power semiconductor die.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of an embodiment of a power device cell.

FIG. 2 illustrates a cross-sectional view of the power device cell, according to another embodiment.

FIG. 3 illustrates a cross-sectional view of the power device cell, according to another embodiment.

FIG. 4 illustrates a cross-sectional view of the power device cell, according to another embodiment.

FIG. 5 illustrates a cross-sectional view of an organic and/or glass electrical insulator of the power device cell, according to an embodiment.

FIG. 6 illustrates a cross-sectional view of a power electronics assembly that includes a printed circuit board (PCB) and the power device cell embedded in the PCB.

FIG. 7 illustrates a cross-sectional view of a power electronics assembly that includes the power device cell, according to another embodiment.

### DETAILED DESCRIPTION

The embodiments described herein provide a power device cell designed for high voltage applications (e.g., 20V up to 1200V or higher) and/or high current applications (e.g., one or more amps up to hundreds or more amps). The power device cell includes a vertical power semiconductor die such as a vertical power transistor die or a vertical power diode die disposed in a recess formed in a first main surface of a metallic body. An organic and/or glass electrical insulator covers the opposite (second) main surface of the metallic body such that the power device cell is electrically insulated at least at a first side that includes the organic and/or glass electrical insulator, with the organic and/or glass electrical insulator being confined to the metallic body. The backside of the vertical power semiconductor die is configured to be at a different electric potential than the frontside of the die, and the metallic body is at the same electric potential as the backside of the vertical power semiconductor die.

The organic and/or glass electrical insulator of the power device cell can be directly attached to the backside of the metallic body or its support. One side of the organic and/or glass electrical insulator may be coated with an electrical and/or thermally conductive layer or foil, e.g., such as adhesive layers between an insulator and conductive layers and/or between a metallic layer of the device cell and the semiconductor die and/or its support and/or between the metallic layer and a cooling support. Both sides of the organic and/or glass electrical insulator may be coated with an electrical and/or thermally conductive layer or foil, e.g., adhesive layers between a tape and conductive layers and/or between a metallic layer of the device cell and the semiconductor die and/or its support and/or between the metallic layer and a cooling support.

The power device cell design described herein offers a low cost alternative to standard power device cells. The assembly process used to produce the vertical power semiconductor die may be used to form the organic and/or glass electrical insulator, offering further cost savings. Low cost and productive embedding of the power device cell into a support such as a PCB (printed circuit board) is realized by eliminating the need to produce a separate laminate layer during the PCB manufacturing process. Good thermal and mechanical adhesion of the power device cell to the support may be realized by a metal-to-metal junction.

Described next, with reference to the figures, are exemplary embodiments of the power device cell design and power electronics assemblies that utilize the power device cell design. Any of the power device cell embodiments described herein may be used interchangeably unless otherwise expressly stated.

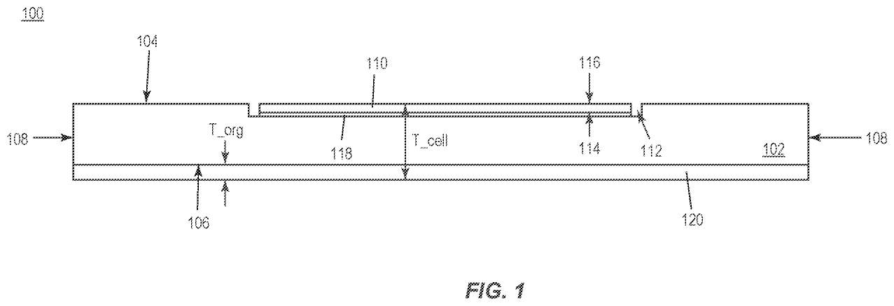

FIG. 1 illustrates a cross-sectional view of an embodiment of a power device cell 100. The power device cell 100 includes a metallic body 102 having a first main surface 104, a second main surface 106 opposite the first main surface 104, and a side face 108 vertically extending between the first main surface 104 and the second main surface 106. A vertical power semiconductor die 110 is disposed in a recess 112 formed in the first main surface 104 of the metallic body 102.

In one embodiment, the metallic body 102 is a Cu (copper) block. Other types of metallic blocks may be used as the metallic body 102, e.g., an Al (aluminum) block. The recess 112 may be formed in the first main surface 104 of the metallic body 102 by stamping, coining, etching, etc. The recess 112 is dimensioned to receive the vertical power semiconductor die 110.

The vertical power semiconductor die 110 is designed for high voltage applications (e.g., 20V up to 1200V or higher) and/or high current applications (e.g., one or more amps up to hundreds or more amps). The backside 114 of the vertical power semiconductor die 110 is configured to be at a different electric potential than the frontside 116 of the vertical power semiconductor die 110. For example, the vertical power semiconductor die 110 may be a vertical power diode die having an anode terminal at the die frontside 116 and a cathode terminal at the die backside 114.

In another embodiment, the vertical power semiconductor die 110 may be a vertical power transistor die having one load terminal at the die frontside 116 and another load terminal at the die backside 114. For example, in the case of a Si (silicon) or SiC (silicon carbide) vertical power MISFET (metal-insulator-semiconductor field-effect transistor), the source terminal and one or more additional terminals such as a gate terminal, sense terminal(s), etc. may be at the die frontside 116 and the drain terminal may be at the die backside 114. In the case of an IGBT (insulated gate bipolar transistor), the emitter terminal and one or more additional terminals such as a gate terminal, sense terminal(s), etc. may be at the die frontside 116 and the collector terminal may be at the die backside 114. Still other types of vertical power devices may be included in the vertical power semiconductor die 110.

The backside 114 of the vertical power semiconductor die 110 is electrically connected to the metallic body 102, e.g., by an electrically conductive die attach material or joint 118 such as solder, an electrically conductive adhesive, a sintered joint, a diffusion soldered joint, a brazed joint, etc. Because the backside 114 of the vertical power semiconductor die 110 is electrically connected to the metallic body 102, the metallic body 102 is at the same electric potential as the backside 114 of the vertical power semiconductor die 110, at both the first and second main surfaces 104, 106 of the metallic body 102. Accordingly, all electrical connections to the vertical power semiconductor die 110 are accessible at the frontside 104 of the power device cell 100. The phrase ‘same electric potential’ as used herein is intended to include the minuscule electric potential drop over the thickness of the metallic body 102 which, of course, is not a perfect electrical conductor. Accordingly, the electrical potential at both main surfaces 104, 106 of the metallic body 102 is considered herein to be the same.

The frontside 116 of the vertical power semiconductor die 110 may be coplanar with the first main surface 104 of the metallic body 102, e.g., as shown in FIG. 1. The frontside 116 of the vertical power semiconductor die 110 may instead lie in a different (higher or lower) plane than the first main surface 104 of the metallic body 102.

In each case, the power device cell 100 also includes an organic and/or glass electrical insulator 120 covering the second main surface 106 of the metallic body 102 such that the power device cell 100 is electrically insulated at least at a first side that includes the organic and/or glass electrical insulator 120. The organic and/or glass electrical insulator 120 is confined to the metallic body 102. That is, the organic and/or glass electrical insulator 120 is limited to the dimensions and shape of the metallic body 102. In FIG. 1, the organic and/or glass electrical insulator 120 is restricted to the second main surface 106 of the metallic body 102. In this embodiment, the organic and/or glass electrical insulator 120 has the same area as the second main surface 106 of the metallic body 102 and delimits the side of the power device cell 100 that is electrically insulated, but the area of the organic and/or glass electrical insulator 120 may also be smaller.

In one embodiment, the organic and/or glass electrical insulator 120 is part of a foil or tape applied to the second main surface 106 of the metallic body 102. For example, the foil or tape may be laminated or glued onto the second main surface 106 of the metallic body 102. In another embodiment, the organic and/or glass electrical insulator 120 is a resist, glue or wax that coats the second main surface 106 of the metallic body 102. In another embodiment, the organic and/or glass electrical insulator 120 comprises plastic. In another embodiment, the organic and/or glass electrical insulator 120 is a glass cloth.

Separately or in combination, the organic and/or glass electrical insulator 120 can withstand temperatures of at least 100 C, 150 C, 175 C, 200 C, 225 C or higher temperature, and has a high breakdown voltage of at least 50V up to 10 kV or higher.

Separately or in combination, the organic and/or glass electrical insulator 120 may have a thickness T_org in a range of 5 mm to 0.01 mm, e.g., 2 mm to 0.05 mm.

Separately or in combination, the power device cell 100 may have a thickness tolerance of +/−100 microns (μm), including the organic and/or glass electrical insulator 120. That is, in some embodiment, the thickness T_cell of the power device cell 100 may vary by no more than +/−100 μm.

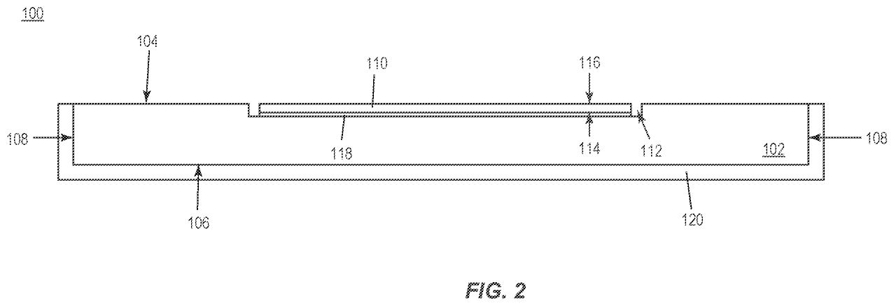

FIG. 2 illustrates a cross-sectional view of the power device cell 100, according to another embodiment. In FIG. 2, the organic and/or glass electrical insulator 120 extends onto the side face 108 of the metallic body 102.

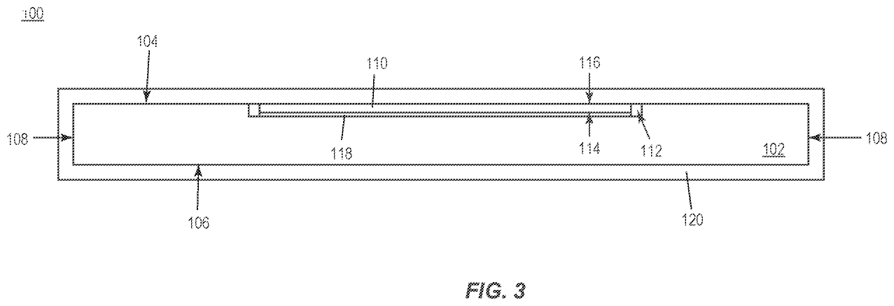

FIG. 3 illustrates a cross-sectional view of the power device cell 100, according to another embodiment. In FIG. 3, the organic and/or glass electrical insulator 120 further extends onto the first main surface 104 of the metallic body 102. Electrical contact to the first main surface 104 of the metallic body 102 and to each terminal at the frontside 116 of the vertical power semiconductor die 110 may be realized by forming openings (not shown in FIG. 3) in the part of the organic and/or glass electrical insulator 120 that covers the first main surface 104 of the metallic body 102 and filling the openings with an electrically conductive material such as Cu. The electrically conductive material may be patterned to ensure that the different electrical potentials of the power device cell 100 remain separate.

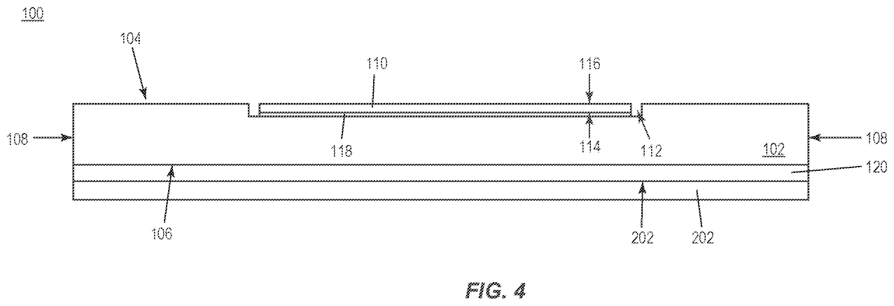

FIG. 4 illustrates a cross-sectional view of the power device cell 100, according to another embodiment. In FIG. 4, the power device cell 100 further includes a metallic layer 200 covering the side 202 of the organic and/or glass electrical insulator 120 that faces away from the metallic body 102. The metallic layer 200 may be a Cu layer, for example. The metallic layer 200 enables a metal-to-metal junction between the device power cell 100 and a support (not shown in FIG. 4) for the device power cell 100, providing enhanced thermal and mechanical adhesion of the power device cell 100 to the support.

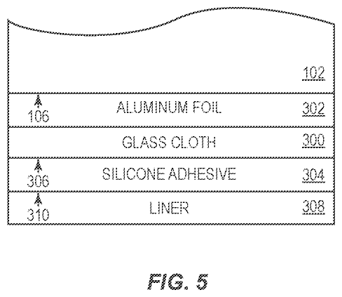

FIG. 5 illustrates a cross-sectional view of the organic and/or glass electrical insulator 120 of the power device cell 100, according to an embodiment. In FIG. 5, the organic and/or glass electrical insulator 120 is a glass cloth 300 that is part of a layer stack. The layer stack also includes an aluminum foil 302 interposed between the glass cloth 300 and the second main surface 106 of the metallic body 102. The layer stack further includes an adhesive 304 such as a silicone adhesive applied to the side 306 of the glass cloth 300 that faces away from the aluminum foil 302 and a release liner 308 applied to the side 310 of the adhesive 304 that faces away from the glass cloth 300.

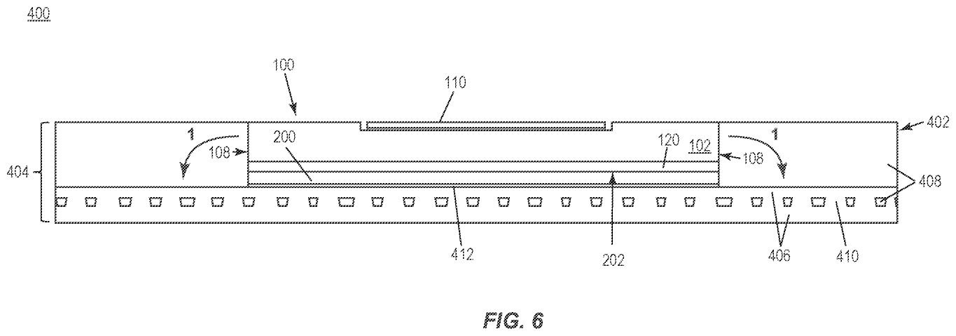

FIG. 6 illustrates a cross-sectional view of a power electronics assembly 400 that includes a printed circuit board (PCB) 402 as a support for the power device cell 100. According to this embodiment, the power device cell 100 is embedded in the PCB 402. The power electronics assembly 400 may form part of a power electronics circuit for use in various power applications such as DC/AC inverters, DC/DC converters, AC/DC converters, DC/AC converters, AC/AC converters, multi-phase inverters, H-bridge, traction inverters, on-board chargers, etc.

A laminated structure 404 of the PCB 402 covers the organic and/or glass electrical insulator 120 of the power device cell 100. Thermal dissipation to the laminated structure 404 of the PCB 402 laterally occurs through the side face 108 of the power device cell 100, as indicated by the arrows labelled ‘1’ in FIG. 6. Since the organic and/or glass electrical insulator 120 is confined to the metallic body 102 of the power device cell 100, the organic and/or glass electrical insulator 120 is present adjacent to only the vertical power semiconductor die 110, i.e., adjacent to only the area of the PCB 402 exposed to high voltage during operation. Accordingly, the power device cell 100 allows for both an improved thermal dissipation and a decreased thickness of the PCB 402 since the PCB 402 does not require an additional laminate layer for electrically insulating the power device cell 100.

The laminated structure 404 of the PCB 402 incudes one or more electrically conductive (re-routing) layers 406 and one or more electrically insulating layers 408. For example, the one or more electrically insulating layers 408 may comprise FR-4 which is a common dielectric material used in PCBs and the one or more electrically conductive layers 406 may be Cu layers. If the PCB 402 includes more than one electrically conductive layer 406, electrically conductive layer vias 410 such as Cu vias interconnect the electrically conductive layers 406 to form a multi-layer PCB.

Also as shown in FIG. 6, the power device cell 100 may include a metallic layer 200 that covers the side 202 of the organic and/or glass electrical insulator 120 that faces away from the metallic body 102 of the device cell 100. According to this embodiment, the metallic layer 200 of the power device cell 100 is attached to a metallic layer 406 of the PCB by a die attach material or joint 412 such as solder, an electrically conductive adhesive, etc.

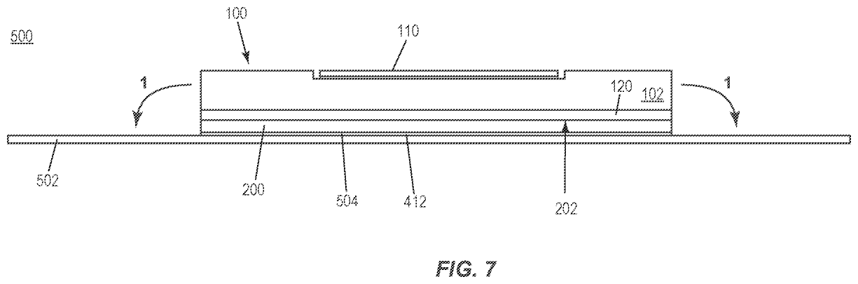

FIG. 7 illustrates a cross-sectional view of a power electronics assembly 500 that includes the power device cell 100, according to another embodiment. The power electronics assembly 500 may form part of a power electronics circuit for use in various power applications such as DC/AC inverters, DC/DC converters, AC/DC converters, DC/AC converters, AC/AC converters, multi-phase inverters, H-bridge, traction inverters, on-board chargers, etc.

In FIG. 7, the power device cell 100 is mounted to a metallic frame 502. The metallic frame 502 that supports the power device cell 100 may be formed by stamping, punching, etching, etc. In one embodiment, the metallic frame 502 is a lead frame (e.g., copper, copper-alloy, iron-nickel alloy, etc.).

Also as shown in FIG. 7, the power device cell 100 may include a metallic layer 200 that covers the side 202 of the organic and/or glass electrical insulator 120 that faces away from the metallic body 102 of the device cell 100. According to this embodiment, the metallic layer 200 of the power device cell 100 is attached to the metallic frame 502 that supports the device cell 100 by a die attach material or joint 504 such as solder, an electrically conductive adhesive, a sintered joint, a diffusion soldered joint, a brazed joint, etc.

Although the present disclosure is not so limited, the following numbered examples demonstrate one or more aspects of the disclosure.

Example 1. A power device cell, comprising: a metallic body having a first main surface, a second main surface opposite the first main surface, and a side face vertically extending between the first main surface and the second main surface; a vertical power semiconductor die in a recess formed in the first main surface of the metallic body; and an organic and/or glass electrical insulator covering the second main surface of the metallic body such that the power device cell is electrically insulated at least at a first side, wherein the organic and/or glass electrical insulator is confined to the metallic body, wherein a backside of the vertical power semiconductor die is configured to be at a different electric potential than a frontside of the vertical power semiconductor die, wherein the metallic body is at the same electric potential as the backside of the vertical power semiconductor die.

Example 2. The power device cell of example 1, wherein the organic and/or glass electrical insulator is part of a foil or tape applied to the second main surface of the metallic body.

Example 3. The power device cell of example 1, wherein the organic and/or glass electrical insulator is a resist, glue or wax that coats the second main surface of the metallic body.

Example 4. The power device cell of example 1, wherein the organic and/or glass electrical insulator comprises plastic.

Example 5. The power device cell of example 1, wherein the organic and/or glass electrical insulator is a glass cloth.

Example 6. The power device cell of example 5, wherein the glass cloth is part of a layer stack that also includes an aluminum foil interposed between the glass cloth and the second main surface of the metallic body, an adhesive applied to a side of the glass cloth that faces away from the aluminum foil, and a liner applied to a side of the adhesive that faces away from the glass cloth.

Example 7. The power device cell of any of examples 1 through 6, wherein the organic and/or glass electrical insulator has the same area as the second main surface of the metallic body.

Example 8. The power device cell of any of examples 1 through 6, wherein the organic and/or glass electrical insulator extends onto the side face of the metallic body.

Example 9. The power device cell of example 8, wherein the organic and/or glass electrical insulator further extends onto the first main surface of the metallic body.

Example 10. The power device cell of any of examples 1 through 9, wherein the organic and/or glass electrical insulator has a thickness in a range of 5 mm to 0.01 mm.

Example 11. The power device cell of example 10, wherein the thickness of the organic and/or glass electrical insulator is in a range of 2 mm to 0.05 mm.

Example 12. The power device cell of any of examples 1 through 10, wherein the power device cell has a thickness tolerance of +/−100 microns, including the organic and/or glass electrical insulator.

Example 13. The power device cell of any of examples 1 through 11, further comprising a metallic layer covering a side of the organic and/or glass electrical insulator that faces away from the metallic body.

Example 14. A power electronics assembly, comprising: a printed circuit board; and a power device cell embedded in the printed circuit board, wherein the power device cell comprises: a metallic body having a first main surface, a second main surface opposite the first main surface, and a side face vertically extending between the first main surface and the second main surface; a vertical power semiconductor die in a recess formed in the first main surface of the metallic body; and an organic and/or glass electrical insulator covering the second main surface of the metallic body such that the power device cell is electrically insulated at least at a first side, wherein the organic and/or glass electrical insulator is confined to the metallic body, wherein a backside of the vertical power semiconductor die is configured to be at a different electric potential than a frontside of the vertical power semiconductor die, wherein the metallic body is at the same electric potential as the backside of the vertical power semiconductor die.

Example 15. The power electronics assembly of example 14, wherein the power device cell further comprises a metallic layer covering a side of the organic and/or glass electrical insulator that faces away from the metallic body, and wherein the metallic layer of the power device cell is attached to a metallic layer of the printed circuit board.

Example 16. The power electronics assembly of example 14 or 15, wherein a laminated structure of the printed circuit board covers the organic and/or glass electrical insulator of the power device cell, and wherein the laminated structure of the printed circuit board comprises one or more electrically conductive layers and one or more electrically insulating layers.

Example 17. A power electronics assembly, comprising: a metallic frame; and a power device cell mounted to the metallic frame, wherein the power device cell comprises: a metallic body having a first main surface, a second main surface opposite the first main surface, and a side face vertically extending between the first main surface and the second main surface; a vertical power semiconductor die in a recess formed in the first main surface of the metallic body; and an organic and/or glass electrical insulator covering the second main surface of the metallic body such that the power device cell is electrically insulated at least at a first side, wherein the organic and/or glass electrical insulator is confined to the metallic body, wherein a backside of the vertical power semiconductor die is configured to be at a different electric potential than a frontside of the vertical power semiconductor die, wherein the metallic body is at the same electric potential as the backside of the vertical power semiconductor die.

Example 18. The power electronics assembly of example 17, wherein the power device cell further comprises a metallic layer covering a side of the organic and/or glass electrical insulator that faces away from the metallic body, and wherein the metallic layer of the power device cell is attached to the metallic frame.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power device cell, comprising:
a metallic body having a first main surface, a second main surface opposite the first main surface, and a side face vertically extending between the first main surface and the second main surface;
a vertical power semiconductor die in a recess formed in the first main surface of the metallic body; and
an organic and/or glass electrical insulator covering the second main surface of the metallic body such that the power device cell is electrically insulated at least at a first side that includes the organic and/or glass electrical insulator,
wherein the organic and/or glass electrical insulator is confined to the metallic body,
wherein a backside of the vertical power semiconductor die is configured to be at a different electric potential than a frontside of the vertical power semiconductor die,
wherein the metallic body is at the same electric potential as the backside of the vertical power semiconductor die.

2. The power device cell of claim 1, wherein the organic and/or glass electrical insulator is part of a foil or tape applied to the second main surface of the metallic body.

3. The power device cell of claim 1, wherein the organic and/or glass electrical insulator is a resist, glue or wax that coats the second main surface of the metallic body.

4. The power device cell of claim 1, wherein the organic and/or glass electrical insulator comprises plastic.

5. The power device cell of claim 1, wherein the organic and/or glass electrical insulator is a glass cloth.

6. The power device cell of claim 5, wherein the glass cloth is part of a layer stack that also includes an aluminum foil interposed between the glass cloth and the second main surface of the metallic body, an adhesive applied to a side of the glass cloth that faces away from the aluminum foil, and a liner applied to a side of the adhesive that faces away from the glass cloth.

7. The power device cell of claim 1, wherein the organic and/or glass electrical insulator has the same area as the second main surface of the metallic body.

8. The power device cell of claim 1, wherein the organic and/or glass electrical insulator extends onto the side face of the metallic body.

9. The power device cell of claim 8, wherein the organic and/or glass electrical insulator further extends onto the first main surface of the metallic body.

10. The power device cell of claim 1, wherein the organic and/or glass electrical insulator has a thickness in a range of 5 mm to 0.01 mm.

11. The power device cell of claim 10, wherein the thickness of the organic and/or glass electrical insulator is in a range of 2 mm to 0.05 mm.

12. The power device cell of claim 1, wherein the power device cell has a thickness tolerance of +/−100 microns, including the organic and/or glass electrical insulator.

13. The power device cell of claim 1, further comprising a metallic layer covering a side of the organic and/or glass electrical insulator that faces away from the metallic body.

14. A power electronics assembly, comprising:
a printed circuit board; and
a power device cell embedded in the printed circuit board,
wherein the power device cell comprises:
a metallic body having a first main surface, a second main surface opposite the first main surface, and a side face vertically extending between the first main surface and the second main surface;
a vertical power semiconductor die in a recess formed in the first main surface of the metallic body; and
an organic and/or glass electrical insulator covering the second main surface of the metallic body such that the power device cell is electrically insulated at least at a first side that includes the organic and/or glass electrical insulator,
wherein the organic and/or glass electrical insulator is confined to the metallic body,
wherein a backside of the vertical power semiconductor die is configured to be at a different electric potential than a frontside of the vertical power semiconductor die,
wherein the metallic body is at the same electric potential as the backside of the vertical power semiconductor die.

15. The power electronics assembly of claim 14, wherein the power device cell further comprises a metallic layer covering a side of the organic and/or glass electrical insulator that faces away from the metallic body, and wherein the metallic layer of the power device cell is attached to a metallic layer of the printed circuit board.

16. The power electronics assembly of claim 14, wherein a laminated structure of the printed circuit board covers the organic and/or glass electrical insulator of the power device cell, and wherein the laminated structure of the printed circuit board comprises one or more electrically conductive layers and one or more electrically insulating layers.

17. A power electronics assembly, comprising:
a metallic frame; and
a power device cell mounted to the metallic frame,
wherein the power device cell comprises:
a metallic body having a first main surface, a second main surface opposite the first main surface, and a side face vertically extending between the first main surface and the second main surface;
a vertical power semiconductor die in a recess formed in the first main surface of the metallic body; and
an organic and/or glass electrical insulator covering the second main surface of the metallic body such that the power device cell is electrically insulated at least at a first side that includes the organic and/or glass electrical insulator,
wherein the organic and/or glass electrical insulator is confined to the metallic body,
wherein a backside of the vertical power semiconductor die is configured to be at a different electric potential than a frontside of the vertical power semiconductor die,
wherein the metallic body is at the same electric potential as the backside of the vertical power semiconductor die.

18. The power electronics assembly of claim 17, wherein the power device cell further comprises a metallic layer covering a side of the organic and/or glass electrical insulator that faces away from the metallic body, and wherein the metallic layer of the power device cell is attached to the metallic frame.
